(19) United States
(12) Patent Application Publication
(10) Pub. No.: US 2026/0171754 A1
(43) Pub. Date: Jun. 18, 2026

(54) Laser array with precise frequency modulation

(71) Applicant: Lyte AI, Inc., Mountain View, CA (US)

(72) Inventors: Adam Scofield, Los Angeles, CA (US); Arman Hajati, San Carlos, CA (US); Alexander Shpunt, Saratoga, CA (US)

(21) Appl. No.: 19/127,110

(22) PCT Filed: Oct. 30, 2023
(86) PCT No.: PCT/US2023/078134

§ 371 Date: May 4, 2025

Related U.S. Application Data
(60) Provisional application No. 63/424,918, filed on Nov. 13, 2022.

(51) Int. Cl. H01S 5/0687; H01S 5/00; H01S 5/12; H01S 5/40

(52) U.S. Cl. CPC H01S 5/0687; H01S 5/0085; H01S 5/12; H01S 5/4025

(57) ABSTRACT

An optoelectronic device (20, 80, 90, 108) includes an array (21) of lasers (22, 24, 26, 28), which are configured to output respective beams. One or more modulators (32, 82) apply frequency modulations to the beams. A single reference interferometer (38, 94) measures a deviation in a respective frequency modulation of at least one of the beams. Correction circuitry (48, 88) applies a feedback correction signal to the modulators to adjust the modulations responsively to the deviation measured by the single reference interferometer.

### CROSS-REFERENCE TO RELATED APPLICATION

This application claims the benefit of U.S. Provisional Patent Application 63/424,918, filed Nov. 13, 2022, which is incorporated herein by reference.

### FIELD

The present invention relates generally to systems and methods for optical sensing, and particularly to sensing using modulated laser beams.

### BACKGROUND

In some sensing applications, such as frequency-modulated continuous-wave (FMCW) LIDAR, the frequency of a coherent beam of light is modulated by application of a radio-frequency (RF) chirp. The chirp may be created, for example, by applying an RF modulation signal to the laser that generates the beam. To reduce sensing errors, it is important that the chirp be linear, i.e., that the frequency of the emitted beam varies linearly over time. Even when the RF modulation signal itself is linear, however, the actual frequency variation of the laser beam during the chirp often includes nonlinear components.

### SUMMARY

Embodiments of the present invention that are described hereinbelow provide improved laser arrays and methods for producing and operating such arrays.

There is therefore provided, in accordance with an embodiment of the invention, an optoelectronic device, including an array of lasers, which are configured to output respective beams. One or more modulators are coupled to apply frequency modulations to the beams. A single reference interferometer is configured to measure a deviation in a respective frequency modulation of at least one of the beams. Correction circuitry is coupled to apply a feedback correction signal to the modulators to adjust the modulations responsively to the deviation measured by the single reference interferometer.

In the disclosed embodiments, the frequency modulations include frequency chirps, and the correction circuitry is configured to linearize the frequency chirps in the beams output by the lasers.

In some embodiments, the device includes a substrate, wherein the lasers and the single reference interferometer are interconnected by waveguides in a photonic integrated circuit (PIC) on the substrate. Typically, the single reference interferometer includes a signal arm and a reference arm, which respectively include a signal waveguide and a reference waveguide disposed on the PIC.

In some embodiments, the array of lasers includes a master laser, which outputs a master beam at a master frequency, and one or more slave lasers, which output respective slave beams at respective slave frequencies. The single reference interferometer is coupled to measure the deviation in the respective frequency modulation of the master beam, and the correction circuitry is configured to correct the deviation measured in the master frequency and to lock the slave frequencies to the master frequency.

In some of these embodiments, the device includes multiple splitters, which are configured split off a master component from the master beam and respective slave components from the slave beams, and one or more heterodyne detectors, which are configured to mix the master component with each of the slave components and to sense, responsively to the mixed master and slave components, respective frequency differences between the master frequency and the slave frequencies. The correction circuitry is configured to lock the slave frequencies responsively to the sensed frequency differences. In a disclosed embodiment, the correction circuitry includes a wavelength locking circuit, which is configured to adjust respective unmodulated wavelengths of the slave lasers responsively to a master wavelength of the master laser. Additionally or alternatively, the correction circuitry is configured to linearize a master frequency chirp of the master beam responsively to the deviation measured by the single reference interferometer and to linearize respective frequency chirps of the slave beams responsively to the sensed frequency differences.

In other embodiments, the device includes an optical multiplexer, which is configured to multiplex the single reference interferometer among the respective beams of the lasers so as to measure respective deviations of the frequency modulation of all the beams, wherein the correction circuitry is configured to apply feedback correction signals to all the modulators responsively to the respective measured deviations. In one embodiment, the optical multiplexer includes an optical switch, which is configured to time-multiplex the single reference interferometer among the respective beams. In another embodiment, the optical multiplexer includes a beam combiner, and the lasers are turned on one at a time so as to time-multiplex the single reference interferometer among the respective beams.

In another embodiment, the lasers have different, respective wavelengths, and the optical multiplexer includes a wavelength multiplexer, which is configured to combine respective parts of the beams at the different wavelengths to form a multispectral input to the single reference interferometer. The single reference interferometer may include a wavelength demultiplexer, which demultiplexes a multispectral output of the reference interferometer among multiple, respective detectors for the different wavelengths.

There is also provided, in accordance with an embodiment of the invention, a method for frequency control, which includes providing an array of lasers, which are configured to output respective beams, and one or more modulators, which are coupled to apply frequency modulations to the beams. The array of lasers is coupled to a single reference interferometer so that the interferometer measures a deviation in a respective frequency modulation of at least one of the beams. A feedback correction signal is applied to the modulators to adjust the modulations responsively to the deviation measured by the single reference interferometer.

There is additionally provided, in accordance with an embodiment of the invention, an optoelectronic device, including an array of lasers, which are configured to output respective beams, and one or more modulators, which are coupled to apply frequency modulations to the beams. One or more reference interferometers, which together include a single signal arm, are configured to measure deviations in respective frequency modulations of one or more of the beams. Correction circuitry is coupled to apply feedback correction signals to the modulators to adjust the modulations responsively to the deviations measured by the one or more reference interferometers.

In some embodiments, the one or more reference interferometers include a single reference interferometer, which includes the single signal arm and a single reference arm.

Alternatively, the one or more reference interferometers include multiple reference interferometers, each coupled to measure a deviation in a respective frequency modulation of a beam output by a respective laser, and the device includes an optical multiplexer, which is configured to multiplex the single signal arm among the multiple reference interferometers. Typically, the multiple reference interferometers each include a respective reference arm coupled to receive a part of the beam output by the respective laser. In a disclosed embodiment, the lasers have different, respective wavelengths, and the optical multiplexer includes a beam combiner, which is configured to combine respective parts of the beams at the different wavelengths to form a multispectral input to the single signal arm.

There is further provided, in accordance with an embodiment of the invention, a method for frequency control, which includes providing an array of lasers, which are configured to output respective beams, and one or more modulators, which are coupled to apply frequency modulations to the beams. The array of lasers is coupled to one or more reference interferometers, which together include a single signal arm, to measure deviations in respective frequency modulations of one or more of the beams. A feedback correction signal is applied to the modulators to adjust the modulations responsively to the deviations measured by the one or more reference interferometers.

The present invention will be more fully understood from the following detailed description of the embodiments thereof, taken together with the drawings in which:

### BRIEF DESCRIPTION OF THE DRAWINGS

FIG. 1 is a block diagram that schematically illustrates a device including a laser array, in accordance with an embodiment of the invention;

FIG. 2 is a block diagram that schematically illustrates a detector used in embodiments of the invention; and

FIG. 3, FIG. 4, and FIG. 5 are block diagrams that schematically illustrate laser arrays, in accordance with alternative embodiments of the invention.

### DETAILED DESCRIPTION

In some sensing systems using CW LIDAR (such as FMCW LIDAR), a small part of the laser beam is split off to a reference interferometer, for example a Mach-Zehnder interferometer comprising two arms of different lengths (commonly referred to as the “signal arm” and the “reference arm”). The laser beam is split between the arms of the reference interferometer, and the beams output from the two arms are mixed and fed to a detector, such as a balanced photodiode pair. The difference between the lengths of the arms gives rise to a frequency difference between the beams upon recombination. The detector measures the resulting beat signal due to interference between the output beams. Nonlinearities in the chirp of the laser beam frequency will give rise to corresponding variations in the beat signal. These variations are measured and fed back to modify the RF modulation signal so as to cancel the nonlinearities in the laser output. Additionally or alternatively, the measured variations are input to signal processing circuits for application of appropriate compensation.

To generate an appreciable beat signal in the reference interferometer, the signal arm should be substantially longer than the reference arm in order to produce a sufficient delay between the output beams. In typical LIDAR applications, for example, the signal arm can be on the order of one to ten meters longer than the reference arm. The long signal arm can be created using an optical fiber, but this solution is impractical for ultra-compact sensing systems, in which the components are fabricated on a photonic integrated circuit (PIC). Therefore, in embodiments of the present invention, the long signal arm of the reference interferometer comprises a waveguide, for example in a coiled or serpentine configuration, which is fabricated on the PIC. This waveguide may consume a substantial fraction of the area of the PIC.

Embodiments of the present invention use an array of multiple semiconductor diode lasers. The use of this sort of array, rather than only a single laser, is helpful in sensing systems, for example, to increase the available optical power and throughput of the system. Although a similar optical power boost could be achieved using a single laser with an array of semiconductor optical amplifiers (SOAs), the use of an array of lasers is advantageous in achieving higher conversion efficiency from electrical to optical power, as well as avoiding the problem of amplified back-reflections from the SOAs to the laser. In some embodiments, the lasers are arranged on a PIC. Alternatively, the laser beams may be coupled to a PIC, for example by edge couplers or grating couplers.

When an array of lasers is used, each laser will typically operate at a different wavelength (either by design or simply due to process variations) and may be characterized by different nonlinearities. Providing each laser with its own reference interferometer, however, would consume an excessive share of the PIC “real estate.”

Therefore, in embodiments of the present invention that are described herein, a single, long signal arm is used in one or more reference interferometers to detect deviations in the respective frequency modulations of an array of lasers. In some embodiments, a single reference interferometer is shared among the array of lasers. In one such embodiment, the reference interferometer is used to linearize the chirp of one of the lasers, which serves as the master laser for purposes of frequency control, and the remaining lasers are locked to the master. In other embodiments, the reference interferometer is multiplexed among the lasers in the array, by time-multiplexing or wavelength-multiplexing, for example. Alternatively, each laser may have its own reference interferometer, while the single signal arm is multiplexed among the referenced interferometers.

The embodiments that are described below relate specifically to arrays of distributed feedback (DFB) diode lasers, which are formed or mounted on a PIC together with the shared reference interferometer. This configuration is particularly useful in ultra-compact, integrated sensing systems. Alternatively, the principles of the present invention may be applied, mutatis mutandis, to lasers of other types, as well as to lasers and sensing systems using multiple PICs and/or optical fibers and other discrete optical components. All such alternative embodiments are considered to be within the scope of the present invention.

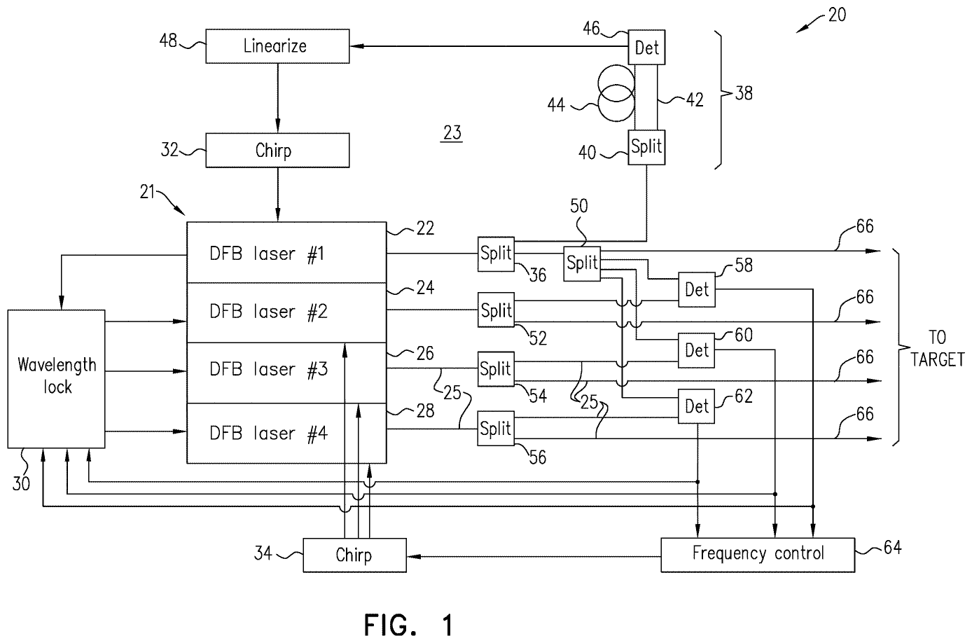

FIG. 1 is a block diagram that schematically illustrates an optoelectronic device 20 comprising a laser array 21, in accordance with an embodiment of the invention. Device 20 can be used, for example, in generating multiple frequency-chirped laser beams 66 for interrogating a target in a coherent sensing application, such as FMCW LIDAR.

It is assumed in this embodiment (as well as in the other embodiments described below) that all the optical and optoelectronic components of device 20, such as lasers, waveguides, mixers, splitters, and detectors, are arranged together on a single PIC 23, having a silicon-on-insulator (SOI) substrate, for example. PIC 23 comprises thin-film layers, which are patterned in a photolithographic process to form waveguides 25 and other optical components on the PIC substrate. The optoelectronic components of device 20 may likewise be formed by appropriate thin film deposition and patterning on the PIC substrate, or they may be produced separately and mounted on PIC 23. The associated electronic circuits, such as modulation and linearization circuits, may likewise be formed on the PIC, or they may be formed on one or more separate electronic integrated circuits, which are mounted on or otherwise connected to the PIC. PCT International Publication WO 2023/076132, whose disclosure is incorporated herein by reference, describes system architectures and methods that may be used for integrating the various optical, optoelectronic, and electronic components of device 20.

In the pictured embodiment, array 21 comprises four DFB lasers 22, 24, 26, 28, of which laser 22 (DFB laser #1) serves as the master for purposes of frequency control and linearization, and the other three lasers 24, 26, 28 are slaves. (Although array 21 and the other laser arrays described hereinbelow each comprise four lasers, the principles of these embodiments may similarly be applied to arrays comprising larger or smaller numbers of lasers.) A modulator 32 applies an RF signal to create a frequency chirp in the output of laser 22. Modulator 32 may either modulate the operating frequency of the laser directly, for example by changing the laser cavity length or the drive current, or it may optically modulate the frequency of the beam that is output by the laser. Other modulators in the disclosed embodiments operate in similar fashion. As noted earlier, even when the frequency of the RF signal changes linearly over time, the resulting change in the laser output frequency typically includes a nonlinear component.

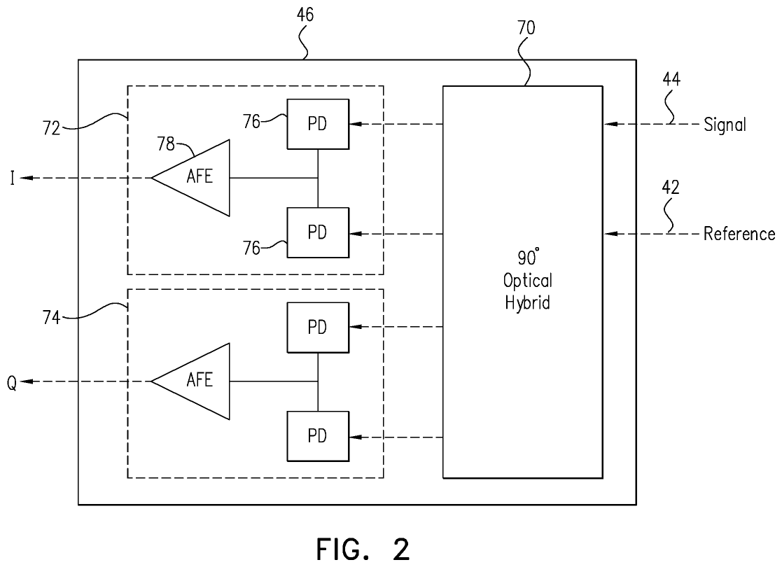

To resolve the nonlinearity in the laser frequency chirp, a splitter 36 splits off a small part of the energy in the beam output by laser 22, for example 1%, for input to a reference interferometer 38. Splitter 36, as well as other splitters and mixers in the disclosed embodiments, may comprise a multimode interferometer (MMI), for example, or any other suitable optical component on PIC 23. Reference interferometer 38 in the pictured embodiments is a Mach-Zehnder interferometer, having a short reference arm 42 and a much longer signal arm 44. Another splitter 40 splits the input to interferometer 38 between signal arm 44 and reference arm 42, for example in a ratio of 50/50 or any other suitable ratio. A detector 46 mixes the optical signals from the signal and reference arms and outputs the resulting electrical beat signal. The detector is described in greater detail hereinbelow with reference to FIG. 2. Other types of reference interferometers may alternatively be used in place of the pictured Mach-Zehnder interferometers.

Variations in the beat signal over time are indicative of nonlinearities in the frequency chirp of the beam that is output by laser 22. A linearization circuit 48 measures these variations and computes a feedback correction signal for input to modulator 32, as shown in FIG. 1. Additionally or alternatively, this correction signal may be used in other compensation methods, such as digital signal processing. The feedback correction signal causes modulator 32 to add a component to the RF signal, which compensates for the measured nonlinear response of the laser.

A wavelength locking circuit 30 adjusts the unmodulated wavelengths of slave lasers 24, 26, 28 to match the unmodulated master wavelength of master laser 22. For this purpose, for example, additional splitters 50, 52, 54, 56 split off small parts of the output beams from each of the lasers for input to respective heterodyne mixers and detectors (Det) 58, 60, 62. Each of these mixer/detectors 58, 60, 62 mixes and measures the frequency difference between master laser 22 and a respective slave laser 24, 26 or 28. Wavelength locking circuit 30 then tunes the slave laser wavelengths either to eliminate the frequency difference or to control it to a desired offset frequency. This tuning function may operate, for example, by adjusting the current injected into lasers 24, 26, 28 and/or adjusting the temperatures of the lasers, for example using a heating element on PIC 23 or on the laser itself.

When the center wavelengths of slave lasers 24, 26, 28 have been properly adjusted, modulators 32 and 34 are turned on to apply frequency chirps to all the lasers, including both the master and the slaves, in mutual synchronization. The chirp of master laser 22 is linearized by means of reference interferometer 38, as explained above. The transfer of master chirp linearity to the slaves can be achieved in several ways. In the pictured embodiment, a frequency control circuit 64 (which may be integrated with or separate from linearization circuit 48) senses the frequency differences between master laser 22 and each of slave lasers 24, 26, 28 during the chirp, based on the signals output by mixer/detectors 58, 60, 62, and generates feedback correction signals to modulator 34. The purpose of these signals is to correct the modulation of slave lasers 24, 26, 28 so that their frequencies precisely track the frequency of master laser 22. Thus, as long as the master laser chirp is linearized, the chirps of the slave lasers will be linearized, as well.

Alternatively, wavelength locking circuit 30 can linearize the chirps of the slave lasers, as well, without the use of an additional frequency control circuit 64. For this purpose, wavelength locking circuit 30 may control the offset between the master and slave laser frequencies not only before turning on modulators 32 and 34, but also while the modulators are in operation, to minimize any undesired frequency offset. To facilitate effective frequency control, a nominal modulation waveform may be fed forward to modulator 34 to reduce the error that wavelength locking circuit 30 must compensate. Methods for iteratively learning or refining the modulation waveforms can be applied to both the master and slave feed-forward components.

Linearization circuit 48, wavelength locking circuit 30, and frequency control circuit 64 are collectively referred to herein as correction circuitry. The components of the correction circuitry typically comprise digital logic circuits coupled to suitable analog front ends, as are known in the art. The analog front ends comprise amplifiers, filters, analog/digital converters and digital/analog converters, for receiving analog input signals from the detectors in device 20 and outputting control signals to the lasers and modulators. The digital logic circuits, which may be hard-wired or programmable, measure deviations in the digitized signals received from the detectors and generate suitable digital waveforms for conversion to analog form and output to the lasers and modulators for correcting the deviations.

FIG. 2 is a block diagram that schematically shows details of detector 46, which can be used in implementing the “Det” blocks in FIG. 1 and in the other embodiments described herein. In this case, the coherent beams from waveguides connected to reference arm 42 and signal arm 44 are input to a 90° optical hybrid 70, which contains two mixers (not shown), with a 90° phase shift applied to one of the beams that is input to one of the mixers. Thus, one of the mixers outputs an in-phase (I) mixed optical component to a first balanced photodiode detector 72, while the other mixer outputs a quadrature (Q) mixed optical component to a second balanced photodiode detector 74. Each of these detectors 72, 74 comprises a pair of photodiodes 76 and an analog front end (AFE) circuit 78, which outputs a resulting electrical signal. Detectors 72 and 74 thus output corresponding I and Q components of the electrical output signal. This I/Q detection configuration is useful in improving the signal/noise ratio (SNR) and linearity of beat frequency detection.

Alternatively, detector 46 and the other “Det” blocks in FIG. 1 may comprise other sorts of mixers and detectors. In some embodiments, these detectors output only a single signal component, rather than separate I and Q components.

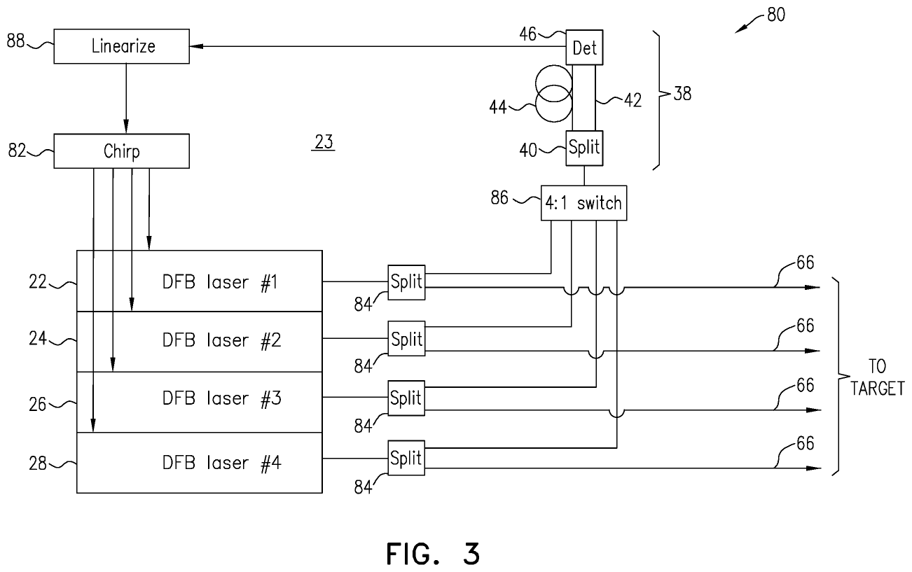

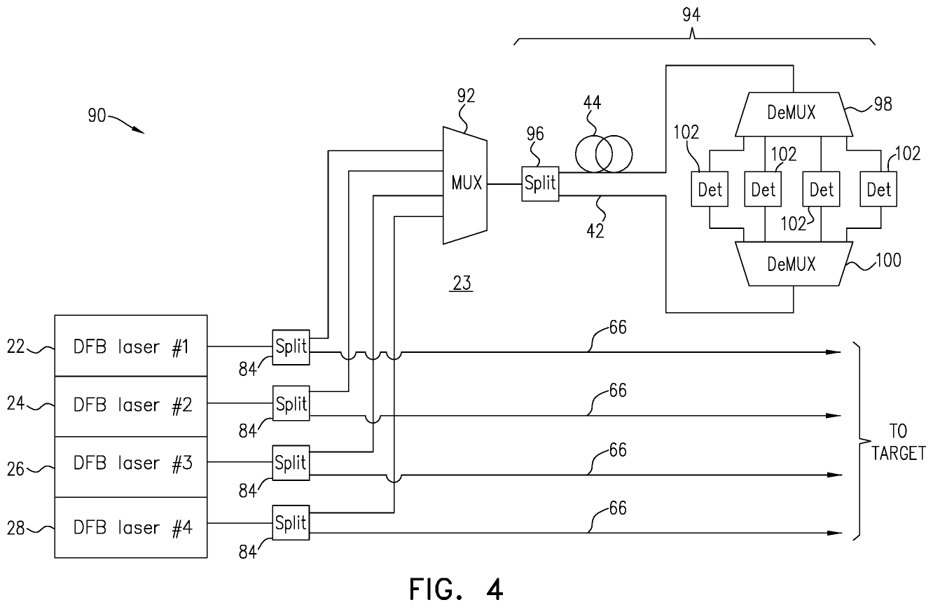

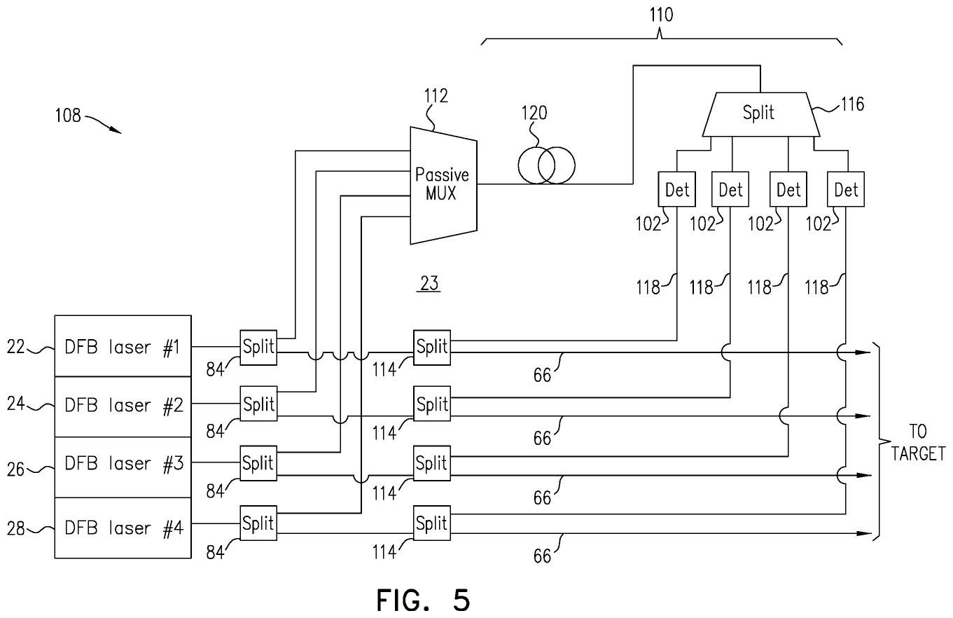

FIG. 3 is a block diagram that schematically illustrates a laser array 80, in accordance with an alternative embodiment of the invention. Array 80 can be used in place of array 21 in device 20 (FIG. 1) in generating multiple linearized frequency-chirped laser beams 66. In this embodiment, however, the lasers in the array operate independently of one another, without necessarily locking their center wavelengths and frequency chirps together, in contrast to the embodiment of FIG. 1. A modulator 82 applies a respective RF signal to each laser 22, 24, 26, 28 in order to create frequency chirps in beams 66.

In the present embodiment, the single reference interferometer 38, comprising reference arm 42 and signal arm 44, is time-multiplexed among lasers 22, 24, 26, 28 in array 80. A respective splitter 84 splits off a small part of each of the laser beams, and a four-way optical switch 86 selects one of these split-off beams for input to reference interferometer 38. A linearization circuit 88 receives and processes the signals output by detector 46 to measure the nonlinearity of the chirp of each laser and to compute and apply a correction to modulator 82 for each laser in turn, independently of the other lasers.

In an alternative embodiment (not shown in the figures), switch 86 is replaced by a passive multiplexer, for example a simple beam combiner. Lasers 22, 24, 26 and 28 can be time-multiplexed, by turning the lasers on one at a time to enable linearization circuit 88 to measure the nonlinearity of the chirp of each laser and to compute the corresponding corrections. Alternatively, the measurements and linearization can be performed on all four lasers operating simultaneously, for example as described below.

FIG. 4 is a block diagram that schematically illustrates a laser array 90, in accordance with yet another embodiment of the invention. Array 90 can also be used in place of array 21 in device 20 (FIG. 1) in generating multiple linearized frequency-chirped laser beams 66. As in the embodiment of FIG. 3, a reference interferometer 94 is multiplexed among the lasers. In the present embodiment, however, wavelength multiplexing is applied so that all the laser beams can use reference interferometer 94 simultaneously. The linearization and modulation circuits are omitted from this figure for the sake of simplicity.

In array 90, each laser 22, 24, 26, 28 operates at a distinct wavelength, for example wavelengths that are 20 nm apart as in communication systems using coarse wavelength division multiplexing (CWDM). A respective splitter 84 splits off a small part of each of the laser beams, and a four-way wavelength multiplexer 92 combines the four beams to create a single multispectral input to reference interferometer 94. At the outputs from signal arm 44 and reference arm 42, wavelength demultiplexers 98, 100 separate the multispectral output of interferometer 94 into multiple beams according to wavelength and input each of the wavelengths to a respective detector 102. The beat signal output by each detector 102 is fed back to control the modulation and linearize the chirp of the corresponding laser.

FIG. 5 is a block diagram that schematically illustrates a laser array 108, in accordance with an alternative embodiment of the invention. As in the preceding embodiments, laser array 108 can be used in place of array 21 in device 20 (FIG. 1) in generating multiple linearized frequency-chirped laser beams 66. In the present embodiment, however, a single signal arm 120 is shared among a set 110 of multiple reference interferometers. Each interferometer in set 110 comprises its own detector 102, which measures the deviation in the respective frequency modulation of beam 66 that is output by a respective laser 22, 24, 26, 28. (The linearization and modulation circuits are omitted from this figure for the sake of simplicity.)

In array 108, each laser 22, 24, 26, 28 operates at a distinct wavelength, but the wavelengths need not be as widely spaced as in the embodiment of FIG. 4. Splitters 84 split off a small part of each of the laser beams, and a four-way passive multiplexer 112 combines the four beams to create a single multispectral input to signal arm 120. At the output from signal arm 120, a passive splitter 116 divides the multispectral beam among detectors 102. Further splitters 114 split off a part of each beam 66 into a respective reference arm 118, which together with the respective detector 102 defines a respective reference interferometer. The use of passive splitting components in this embodiment is useful in reducing the overall size of array 108, as well as reducing the spectral range of the wavelengths relative to the WDM scheme used in the embodiment of FIG. 4.

The beat signal output by each detector 102 is fed back to control the modulation and linearize the chirp of the corresponding laser 22, 24, 26, or 28. Because of the different wavelengths of the lasers in this embodiment, each detector 102 will receive a reference signal from the respective reference arm 118 at the wavelength of the corresponding laser. The beat signal at each detector 102 will comprise a strong, low-frequency component due to interference between this reference signal and the part of the multispectral signal received from signal arm 120 at the wavelength of the reference signal. The parts of the multispectral signal at the other wavelengths will not contribute to this beat signal.

Although the embodiments described above refer specifically to linearization of the chirp of the laser beams, the principles of these embodiments may also be applied, mutatis mutandis, in generating other sorts of modulation profiles, which are not necessarily linear.

Furthermore, although the present embodiments and the claims relate to the use of a single reference interferometer or a single signal arm shared among multiple reference interferometers to adjust the modulations of an array of lasers, in practical devices with large arrays of lasers, the array may be divided into multiple sub-arrays, each comprising two or more lasers, with a single, respective reference interferometer or signal arm serving each sub-array. Each sub-array in this case can itself be considered an “array,” and such devices are thus within the scope of the present invention.

It will thus be understood that the embodiments described above are cited by way of example, and the present invention is not limited to what has been particularly shown and described hereinabove. Rather, the scope of the present invention includes both combinations and subcombinations of the various features described hereinabove, as well as variations and modifications thereof which would occur to persons skilled in the art upon reading the foregoing description and which are not disclosed in the prior art.

1. An optoelectronic device, comprising:
an array of lasers, which are configured to output respective beams;
one or more modulators, which are coupled to apply frequency modulations to the beams;
a single reference interferometer, which is configured to measure a deviation in a respective frequency modulation of at least one of the beams; and
correction circuitry, which is coupled to apply a feedback correction signal to the modulators to adjust the modulations responsively to the deviation measured by the single reference interferometer.

2. The device according to claim 1, wherein the frequency modulations comprise frequency chirps, and wherein the correction circuitry is configured to linearize the frequency chirps in the beams output by the lasers.

3. The device according to claim 1, and comprising a substrate, wherein the lasers and the single reference interferometer are interconnected by waveguides in a photonic integrated circuit (PIC) on the substrate.

4. The device according to claim 3, wherein the single reference interferometer comprises a signal arm and a reference arm, which respectively comprise a signal waveguide and a reference waveguide disposed on the PIC.

5. The device according to claim 1, wherein the array of lasers comprises a master laser, which outputs a master beam at a master frequency, and one or more slave lasers, which output respective slave beams at respective slave frequencies, and
wherein the single reference interferometer is coupled to measure the deviation in the respective frequency modulation of the master beam, and the correction circuitry is configured to correct the deviation measured in the master frequency and to lock the slave frequencies to the master frequency.

6. The device according to claim 5, and comprising:
multiple splitters, which are configured split off a master component from the master beam and respective slave components from the slave beams; and
one or more heterodyne detectors, which are configured to mix the master component with each of the slave components and to sense, responsively to the mixed master and slave components, respective frequency differences between the master frequency and the slave frequencies,
wherein the correction circuitry is configured to lock the slave frequencies responsively to the sensed frequency differences.

7. The device according to claim 6, wherein the correction circuitry comprises a wavelength locking circuit, which is configured to adjust respective unmodulated wavelengths of the slave lasers responsively to a master wavelength of the master laser.

8. The device according to claim 6, wherein the correction circuitry is configured to linearize a master frequency chirp of the master beam responsively to the deviation measured by the single reference interferometer and to linearize respective frequency chirps of the slave beams responsively to the sensed frequency differences.

9. The device according to claim 1, and comprising an optical multiplexer, which is configured to multiplex the single reference interferometer among the respective beams of the lasers so as to measure respective deviations of the frequency modulation of all the beams,
wherein the correction circuitry is configured to apply feedback correction signals to all the modulators responsively to the respective measured deviations.

10. The device according to claim 9, wherein the optical multiplexer comprises an optical switch, which is configured to time-multiplex the single reference interferometer among the respective beams.

11. The device according to claim 9, wherein the optical multiplexer comprises a beam combiner, and wherein the lasers are turned on one at a time so as to time-multiplex the single reference interferometer among the respective beams.

12. The device according to claim 9, wherein the lasers have different, respective wavelengths, and the optical multiplexer comprises a wavelength multiplexer, which is configured to combine respective parts of the beams at the different wavelengths to form a multispectral input to the single reference interferometer.

13. The device according to claim 12, wherein the single reference interferometer comprises a wavelength demultiplexer, which demultiplexes a multispectral output of the reference interferometer among multiple, respective detectors for the different wavelengths.

14. A method for frequency control, comprising:
providing an array of lasers, which are configured to output respective beams, and one or more modulators, which are coupled to apply frequency modulations to the beams;
coupling the array of lasers to a single reference interferometer so that the interferometer measures a deviation in a respective frequency modulation of at least one of the beams; and
applying a feedback correction signal to the modulators to adjust the modulations responsively to the deviation measured by the single reference interferometer.

15-26. (canceled)

27. An optoelectronic device, comprising:
an array of lasers, which are configured to output respective beams;
one or more modulators, which are coupled to apply frequency modulations to the beams;
one or more reference interferometers, which together comprise a single signal arm and which are configured to measure deviations in respective frequency modulations of one or more of the beams; and
correction circuitry, which is coupled to apply feedback correction signals to the modulators to adjust the modulations responsively to the deviations measured by the one or more reference interferometers.

28. The device according to claim 27, wherein the frequency modulations comprise frequency chirps, and wherein the correction circuitry is configured to linearize the frequency chirps in the beams output by the lasers.

29. The device according to claim 27, and comprising a substrate, wherein the lasers and the one or more reference interferometers are interconnected by waveguides in a photonic integrated circuit (PIC) on the substrate.

30. The device according to claim 27, wherein the one or more reference interferometers comprise a single reference interferometer, which comprises the single signal arm and a single reference arm.

31. The device according to claim 30, and comprising an optical multiplexer, which is configured to multiplex the single reference interferometer among the respective beams of the lasers so as to measure respective deviations of the frequency modulation of all the beams.

32. The device according to claim 27, wherein the one or more reference interferometers comprise multiple reference interferometers, each coupled to measure a deviation in a respective frequency modulation of a beam output by a respective laser, and wherein the device comprises an optical multiplexer, which is configured to multiplex the single signal arm among the multiple reference interferometers.

33-42. (canceled)
